(19) United States
(12) Patent Application Publication
(10) Pub. No.: US 2025/0266384 A1
(43) Pub. Date: Aug. 21, 2025

(54) SEMICONDUCTOR PACKAGE

(71) Applicant: Samsung Electronics Co., Ltd., Suwon-si (KR)

(72) Inventors: Yunhee LEE, Suwon-si (KR); Jaesun KIM, Suwon-si (KR); Seunggeol RYU, Suwon-si (KR); Seungsoo HA, Suwon-si (KR)

(73) Assignee: Samsung Electronics Co., Ltd., Suwon-si (KR)

(21) Appl. No.: 19/011,910

(22) Filed: Jan. 7, 2025

(30) Foreign Application Priority Data
Feb. 15, 2024 (KR) 10-2024-0022002

(51) Int. Cl. H01L 23/00; H01L 23/538; H01L 25/00; H01L 25/18; H10D 1/68

(52) U.S. Cl. CPC H01L 24/24; H01L 25/18; H01L 25/50; H10D 1/68; H01L 23/5383; H01L 2224/24146

(57) ABSTRACT

A semiconductor package may include a first upper semiconductor chip on a top surface of a first interposer. The first interposer may include a lower redistribution structure, an upper redistribution structure, conductive posts between the lower redistribution structure and the upper redistribution structure, a first passive element, and a first internal semiconductor chip. The lower redistribution structure may include a lower redistribution pattern and a lower insulating layer. The upper redistribution structure may include an upper redistribution pattern and an upper insulating layer above the lower redistribution structure. The first passive element and the first internal semiconductor chip may be between the upper redistribution structure and the lower redistribution structure and laterally apart from the conductive posts. The first passive element may be a ceramic capacitor.

### CROSS-REFERENCE TO RELATED APPLICATION

This application is based on and claims priority under 35 U.S.C. § 119 to Korean Patent Application No. 10-2024-0022002, filed on Feb. 15, 2024 in the Korean Intellectual Property Office, the disclosure of which is incorporated by reference herein in its entirety.

### BACKGROUND

Inventive concepts relate to a semiconductor package, and more particularly, to a semiconductor package including an interposer.

In accordance with the rapid development of the electronics industry and user demand, electronic devices are becoming smaller and lighter. Accordingly, a semiconductor package including a plurality of semiconductor chips may be required. As each of the plurality of semiconductor chips included in a semiconductor package becomes more highly integrated, there are cases in which printed circuit boards (PCB) may not accommodate such integration, and a semiconductor package connecting a plurality of semiconductor chips to a PCB with an interposer is being developed.

### SUMMARY

Inventive concepts relate to a semiconductor package with improved economic feasibility and electrical characteristics.

The problems to be solved by technical ideas of inventive concepts are not limited to the above-mentioned problems, and other problems not mentioned will be clearly understood by those skilled in the art from the following description.

According to an example embodiment of inventive concepts, a semiconductor package may include a first upper semiconductor chip and a first interposer, the first upper semiconductor chip on a top surface of the first interposer. The first interposer may include a lower redistribution structure, an upper redistribution structure, conductive posts between the lower redistribution structure and the upper redistribution structure, a first passive element, and a first internal semiconductor chip. The lower redistribution structure may include a lower redistribution pattern and a lower insulating layer. The upper redistribution structure may include an upper redistribution pattern and an upper insulating layer above the lower redistribution structure. The first passive element and the first internal semiconductor chip may be between the upper redistribution structure and the lower redistribution structure and laterally apart from the conductive posts. The first passive element may be a ceramic capacitor.

According to an example embodiment of inventive concepts, a semiconductor package may include a lower redistribution structure including a lower redistribution pattern and a plurality of lower insulating layers; conductive posts, a passive element, and internal semiconductor chips, laterally apart from each other on the lower redistribution structure; an upper redistribution structure connected to the conductive posts, the passive element and the internal semiconductor chips, respectively, the upper redistribution structure being on the conductive posts, the passive element, and the internal semiconductor chips, and the upper redistribution structure including an upper redistribution pattern and a plurality of upper insulating layers; an encapsulant covering the conductive posts, the passive element, and the internal semiconductor chips, the encapsulant between the upper redistribution structure and the lower redistribution structure; intermediate connection vias connected to upper portions of both terminals of the passive element, respectively; internal connection terminals are connected to lower portions of both terminals of the passive element, respectively; a connection pillar connecting the internal semiconductor chips to the upper redistribution pattern; and upper semiconductor chips laterally apart from each other on the upper redistribution structure, wherein the passive element may be a ceramic capacitor, the intermediate connection vias may extend through the encapsulant from top surfaces of both terminals of the passive element to the upper redistribution structure, the intermediate connection vias may be connected to the upper redistribution pattern, and the internal connection terminals may be connected to the lower redistribution pattern.

According to an example embodiment of inventive concepts, a semiconductor package may include a first upper semiconductor chip; a second upper semiconductor chip laterally apart from the first upper semiconductor chip; a first interposer, the first upper semiconductor chip and the second upper semiconductor chip being on a top surface of the first interposer, the first interposer including a lower redistribution structure, an upper redistribution structure, conductive posts between the lower redistribution structure and the upper redistribution structure, a first passive element, a first internal semiconductor chip, a second internal semiconductor chip, and an encapsulant; intermediate connection vias; internal connection terminals; a connection pillar; and an adhesive film. The lower redistribution structure may include a lower redistribution pattern and a lower insulating layer. The upper redistribution structure may include an upper redistribution pattern and an upper insulating layer. The first passive element, the first internal semiconductor chip, and the second internal semiconductor chip may be between the upper redistribution structure and the lower redistribution structure and laterally apart from the conductive posts. The encapsulant may cover the conductive posts, the first passive element, the first internal semiconductor chip, and the second internal semiconductor chip. The encapsulant may be between the upper redistribution structure and the lower redistribution structure. The intermediate connection vias may be connected to upper portions of both terminals of the first passive element. The internal connection terminals may be connected to lower portions of both terminals of the passive element, respectively. The connection pillar may connect the upper redistribution pattern to the first internal semiconductor chip and the second internal semiconductor chip. The adhesive film may be between the first internal semiconductor chip and the lower redistribution structure. The first passive element may be a ceramic capacitor and may vertically overlap the first upper semiconductor chip. The intermediate connection vias may extend through the encapsulant from top surfaces of both terminals of the passive element to the upper redistribution structure and may be connected to the upper redistribution pattern. The internal connection terminals may be connected to the lower redistribution pattern, the intermediate connection via, the first passive element. The internal connection terminals may be configured to pass part of a signal transmitted between the first upper semiconductor chip and the lower redistribution structure. The first internal semiconductor chip may include a silicon capacitor. The first internal semiconductor chip vertically may overlap the first upper semiconductor chip. A part of the second internal semiconductor chip may vertically overlap the first upper semiconductor chip. An other part of the second internal semiconductor chip may vertically overlap the second upper semiconductor chip. A rest of the second internal semiconductor chip may not vertically overlap the first upper semiconductor chip and the second upper semiconductor chip. The upper redistribution structure and the second internal semiconductor chip may be configured to perform signal transmission between the first upper semiconductor chip and the second upper semiconductor chip. Top surfaces of the conductive posts, a top surface of the intermediate connection via, a top surface of the connection pillar, and a top surface of the encapsulant may be coplanar.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is a plan view illustrating a semiconductor package according to an embodiment;

FIG. 3 is a cross-sectional view illustrating a semiconductor package according to an embodiment;

FIG. 4 is a plan view illustrating a semiconductor package according to an embodiment;

FIG. 5 is a plan view illustrating a semiconductor package according to an embodiment;

FIG. 6 is a plan view illustrating a semiconductor package according to an embodiment; and

FIGS. 7A to 7J are cross-sectional views illustrating a method of manufacturing a semiconductor package according to an embodiment.

### DETAILED DESCRIPTION OF THE EMBODIMENTS

Hereinafter, embodiments of inventive concepts will be described in detail with reference to the accompanying drawings.

Embodiments of inventive concepts are provided to more fully explain the technical ideas of inventive concepts to those skilled in the art, and the following embodiments may be modified into various other forms, and the scope of the technical ideas of inventive concepts are not limited to the following embodiments. Rather, these embodiments are provided to make the present disclosure more faithful and complete and to fully convey the technical ideas of inventive concepts to those skilled in the art. In addition, in the drawings, a thickness or size of each layer is exaggerated for convenience and clarity of explanation.

In the current specification, a first direction may refer to an X direction, a second direction may refer to a Y direction, and the first direction and the second direction may be perpendicular to each other. A third direction may be a Z direction, and the third direction may be perpendicular to each of the first direction and the second direction. A horizontal plane or plane refers to an X-Y plane. A top surface of a specific object refers to a surface positioned in a positive third direction with respect to the specific object, and a bottom surface of a specific object refers to a surface positioned in a negative third direction with respect to the specific object.

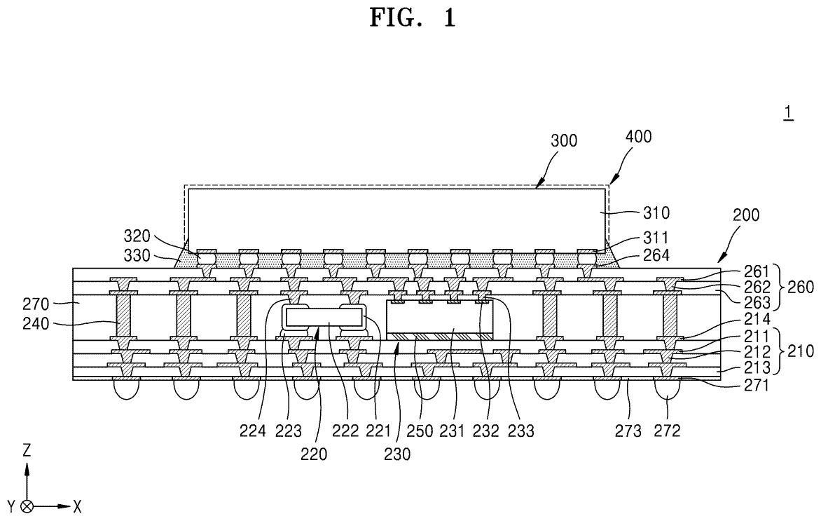

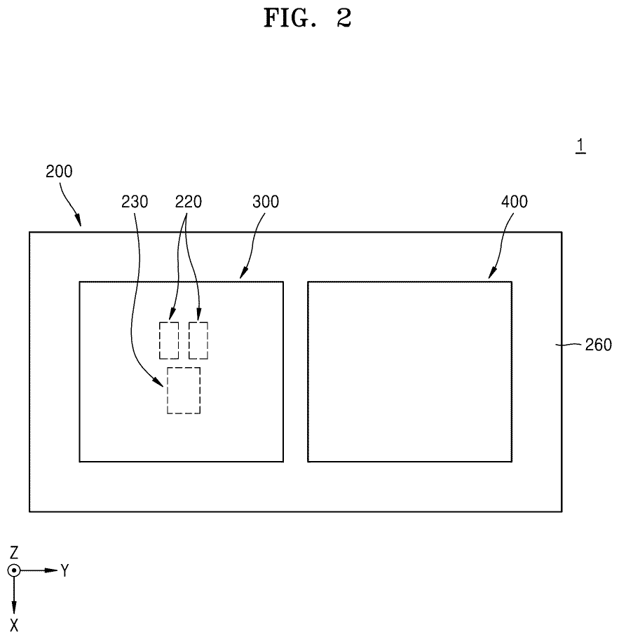

FIG. 1 is a cross-sectional view illustrating a semiconductor package 1 according to one of embodiments. FIG. 2 is a plan view illustrating a semiconductor package 1 according to one of embodiments.

Referring to FIGS. 1 and 2, the semiconductor package 1 may include an interposer 200 and a first upper semiconductor chip 300 and a second upper semiconductor chip 400 arranged on a top surface of the interposer 200. In an embodiment, three or more upper semiconductor chips including the first upper semiconductor chip 300 and the second upper semiconductor chip 400 may be arranged on the top surface of the interposer 200.

The interposer 200 may include a lower redistribution structure 210, an upper redistribution structure 260 arranged above the lower redistribution structure 210 to be apart from the lower redistribution structure 210, a plurality of conductive posts 240 arranged between the lower redistribution structure 210 and the upper redistribution structure 260, a first passive element 220 arranged on a top surface of the lower redistribution structure 210, a first internal semiconductor chip 230 arranged on the top surface of the lower redistribution structure 210 and laterally apart from the first passive element 220, and an encapsulant 270 surrounding the plurality of conductive posts 240, the first passive element 220, and the first internal semiconductor chip 230 between the lower redistribution structure 210 and the upper redistribution structure 260.

The lower redistribution structure 210 may include a plurality of lower insulating layers 213, a plurality of lower redistribution line patterns 211 arranged on at least part of a top or bottom surface of each of the plurality of lower insulating layers 213, and a plurality of lower redistribution via patterns 212 each contacting part of each of the plurality of lower redistribution line patterns 211 through at least one layer of the plurality of lower insulating layers 213. The plurality of lower redistribution line patterns 211 and the plurality of lower redistribution via patterns 212 may be collectively referred to as lower redistribution patterns.

Each of the plurality of lower insulating layers 213 may include, for example, a material layer including an organic compound. In some embodiments, each of the plurality of lower insulating layers 213 may include a material layer including an organic polymer material. In some embodiments, each of the plurality of lower insulating layers 213 may include photosensitive polyimide (PSPI).

Each of the lower redistribution line pattern 211 and the lower redistribution via pattern 212 may include a metal such as copper (Cu), tungsten (W), titanium (Ti), titanium tungsten (TiW), titanium nitride (TiN), tantalum (TaN), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), an alloy thereof, or metal nitride thereof. However, inventive concepts are not limited thereto.

Each of the lower redistribution line pattern 211 and the lower redistribution via pattern 212 may include a seed layer contacting the lower insulating layer 213 and a conductive material layer on the seed layer. In some embodiments, the seed layer may be formed by performing physical vapor deposition (PVD), and the conductive material layer may be formed by performing electroless plating. Part of the lower redistribution line pattern 211 may be formed together with part of the lower redistribution via pattern 212 to form an integrated unit. For example, the lower redistribution line pattern 211 may be formed together with part of the lower redistribution via pattern 212 contacting an upper side of the lower redistribution line pattern 211 or part of the lower redistribution via pattern 212 contacting a lower side of the lower redistribution line pattern 211 to form an integrated unit.

The lower redistribution line pattern 211 may be arranged between two adjacent layers among the plurality of lower insulating layers 213, and on a top surface of the uppermost layer and/or a bottom surface of the lowermost layer among the plurality of lower insulating layers 213.

A plurality of external connection pads 271 may be provided on a bottom surface of the lower redistribution structure 210. A plurality of external connection terminals 272 may be arranged on bottom surfaces of the plurality of external connection pads 271, respectively. The plurality of external connection pads 271 may be connected to an external electronic device, for example, a printed circuit board (PCB) through the plurality of external connection terminals 272.

The plurality of conductive posts 240, the first passive element 220, and the first internal semiconductor chip 230 may be arranged on the lower redistribution structure 210. The first passive element 220 and the first internal semiconductor chip 230 may be arranged on the lower redistribution structure 210 to be laterally apart from each other. Each of the plurality of conductive posts 240 may be arranged on the lower redistribution structure 210 to be apart from the first passive element 220 and the first internal semiconductor chip 230. For example, the plurality of conductive posts 240 may include the same material as the lower redistribution line pattern 211 or the lower redistribution via pattern 212.

The plurality of conductive posts 240 may be arranged on some of the plurality of lower redistribution line patterns 211, respectively. Among the plurality of lower redistribution line patterns 211, some provided on the top surface of the lower redistribution structure 210 may be referred to as a plurality of internal connection pads 214. The plurality of conductive posts 240 may be arranged on some of the plurality of internal connection pads 214, respectively. The first passive element 220 may be arranged on some of the plurality of internal connection pads 214. The first internal semiconductor chip 230 may not be arranged on the plurality of internal connection pads 214.

The first passive element 220 may include a passive element body 222 and terminals 221 surrounding both ends of the passive element body 222. The first passive element 220 may be a ceramic capacitor. For example, the first passive element 220 may include a capacitor element such as a low inductance ceramic capacitor (LICC) and a multi-layered ceramic capacitor (MLCC).

The LICC may be mainly used for high-frequency applications, and the MLCC may be used for low- and mid-frequency applications. Meanwhile the LICC has low inductance characteristics, the MLCC may provide relatively high electrical capacitance through a multi-layered structure. If necessary, a plurality of first passive elements 220 may be included in the interposer 200, and the first passive element 220 may be selected from ceramic capacitors including the LICC and the MLCC and may be provided in the interposer 200 if necessary.

The first passive element 220 may be connected to some of the plurality of internal connection pads 214 through internal connection terminals 223. The first passive element 220 may be a surface-mount device (SMD). The internal connection terminals 223 may provide an electrical connection between the first passive element 220 and the internal connection pads 214. The internal connection terminals 223 may include solder balls or solder paste. Accordingly, the first passive element 220 may be electrically connected to the lower redistribution line pattern 211 and the lower redistribution via pattern 212 of the lower redistribution structure 210. The first passive element 220 may provide various functions such as decoupling, filtering, and resonance attenuation to the semiconductor package 1.

The first internal semiconductor chip 230 may be attached onto the lower redistribution structure 210 by, for example, a die adhesive film 250. In some embodiments, the first internal semiconductor chip 230 may be attached to a top surface of the uppermost layer among the plurality of lower insulating layers 213 included in the lower redistribution structure 210.

The first internal semiconductor chip 230 may include an internal substrate 231 and internal chip pads 232. The internal substrate 231 may be a semiconductor substrate. For example, the internal substrate 231 may include silicon (Si). The first internal semiconductor chip 230 may be a silicon capacitor.

The upper redistribution structure 260 may be positioned on the plurality of conductive posts 240, the first passive element 220, and the first internal semiconductor chip 230. The upper redistribution structure 260 may include at least one upper insulating layer 263, a plurality of upper redistribution line patterns 261 arranged on a top or bottom surface of the at least one upper insulating layer 263, and a plurality of upper redistribution via patterns 262 contacting some of the plurality of upper redistribution line patterns 261 through the upper insulating layer 263. The plurality of upper redistribution line patterns 261 and the plurality of upper redistribution via patterns 262 may be collectively referred to as upper redistribution patterns.

Because the upper redistribution line pattern 261, the upper redistribution via pattern 262, and the upper insulating layer 263 are generally the same as the lower redistribution line pattern 211, the lower redistribution via pattern 212, and the lower insulating layer 213, respectively, detailed description thereof is omitted.

The number of upper insulating layers 263 of the upper redistribution structure 260 may be equal to or less than the number of lower insulating layers 213 of the lower redistribution structure 210. For example, the lower redistribution structure 210 may have at least three lower insulating layers 213, and the upper redistribution structure 260 may have two upper insulating layers 263 less than the number of lower insulating layers 213 of the lower redistribution structure 210.

The plurality of conductive posts 240 may connect the plurality of lower redistribution line patterns 211 of the lower redistribution structure 210 to the plurality of upper redistribution line patterns 261 of the upper redistribution structure 260, respectively. For example, the plurality of conductive posts 240 may be provided on the plurality of internal connection pads 214 arranged on the uppermost surface of the lower redistribution structure 210 among the plurality of upper redistribution line patterns 261. The plurality of conductive posts 240 may contact some of the plurality of upper redistribution line patterns 261 arranged on a bottom surface of the upper redistribution structure 260. The plurality of conductive posts 240 may electrically connect the plurality of internal connection pads 214 to some of the plurality of upper redistribution line patterns 261 arranged on the bottom surface of the upper redistribution structure 260.

Connection pillars 233 may connect the first internal semiconductor chip 230 to the upper redistribution patterns of the upper redistribution structure 260. The connection pillars 233 may be arranged on the internal chip pads 232 to extend in the vertical direction and may be electrically connected to the upper redistribution patterns included in the upper redistribution structure 260.

The first passive element 220 may be connected to intermediate connection vias 224. The intermediate connection vias 224 may be connected to the terminals 221 on the terminals 221 positioned at both ends of the first passive element 220. The intermediate connection vias 224 may be provided through the encapsulant 270 from a top surface of the encapsulant 270, that is, the bottom surface of the upper redistribution structure 260 to the terminals 221 provided at both ends of the first passive element 220.

The encapsulant 270 surrounding the connection pillars 233, the plurality of conductive posts 240, the first passive element 220, the intermediate connection vias 224, and the first internal semiconductor chip 230 may be provided between the lower redistribution structure 210 and the upper redistribution structure 260. The encapsulant 270 may include an epoxy molding compound (EMC) or a polymer material.

Side surfaces of the lower redistribution structure 210, side surfaces of the encapsulant 270, and side surfaces of the upper redistribution structure 260 may be aligned with one another in the vertical direction.

As described above, under the terminals 221 positioned at both ends of the first passive element 220, the internal connection terminals 223 respectively connected to the terminals 221 provide electrical connection between the lower redistribution patterns and the first passive element 220. In addition, the intermediate connection vias 224 respectively connected to the terminals 221 provide electrical connection between the upper redistribution patterns and the first passive element 220. Electrical connection between the upper redistribution patterns and the lower redistribution patterns may be provided through the plurality of conductive posts 240 and the first passive element 220.

Due to the manufacturing processes of the semiconductor package 1 to be described later, top surfaces of the plurality of conductive posts 240, top surfaces of the intermediate connection vias 224, top surfaces of the connection pillars 233, and the top surface of the encapsulant 270 may be coplanar.

The first upper semiconductor chip 300 may be provided on the upper redistribution structure 260. In an embodiment, a second upper semiconductor chip 400 laterally apart from the first upper semiconductor chip 300 may be provided on the upper redistribution structure 260. The first upper semiconductor chip 300 may include, for example, a central processing unit (CPU) chip, a graphics processing unit (GPU) chip, or an application processor (AP) chip.

The second upper semiconductor chip 400 may include, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

In some embodiments, the first upper semiconductor chip 300 may be a CPU chip, a GPU chip, or an AP chip, and the second upper semiconductor chip 400 may be a DRAM chip, an SRAM chip, a flash memory chip, an EEPROM chip, a PRAM chip, an MRAM chip, or an RRAM chip.

The first upper semiconductor chip 300 includes a first upper semiconductor substrate 310 and a plurality of first upper chip pads 311 arranged on a bottom surface of the first upper semiconductor substrate 310. Like the first upper semiconductor chip 300, the second upper semiconductor chip 400 may include a second upper semiconductor substrate and a plurality of second upper chip pads arranged on a bottom surface of the second upper semiconductor substrate.

The plurality of first upper chip pads 311 of the first upper semiconductor chip 300 and the plurality of second upper chip pads of the second upper semiconductor chip 400 may be connected to a plurality of upper connection pads 264 of the upper redistribution structure 260 through a plurality of chip connection members 320, respectively. The plurality of upper connection pads 264 may be electrically connected to the plurality of upper redistribution line patterns 261 and the plurality of upper redistribution via patterns 262 of the upper redistribution structure 260. The chip connection member 320 may be, for example, a bump, a solder ball, or a conductive pillar.

The first upper semiconductor substrate 310 may include, for example, silicon (Si). Alternatively, the first upper semiconductor substrate 310 may include a semiconductor element such as germanium (Ge), or a compound semiconductor such as silicon carbide (SiC), gallium arsenide (GaAs), indium arsenide (InAs), or indium phosphide (InP). The first upper semiconductor substrate 310 may have an active surface and an inactive surface opposite to the active surface. In some embodiments, the active surface of the first upper semiconductor substrate 310 may face the upper redistribution structure 260.

A semiconductor device including a plurality of various types of individual devices may be formed on the active surface of the first upper semiconductor substrate 310. Contents of the second upper semiconductor substrate may also be similar to those of the first upper semiconductor substrate 310.

An underfill material layer 330 surrounding the plurality of chip connection members 320 may fill a space between the first upper semiconductor chip 300 and the upper redistribution structure 260. The underfill material layer 330 may include, for example, an epoxy resin formed by a capillary under-fill method. In some embodiments, the underfill material layer 330 may be a non-conductive film (NCF).

The semiconductor package 1 may be, for example, a fan-out package. As illustrated in FIG. 2, a footprint occupied by the first upper semiconductor chip 300 and the second upper semiconductor chip 400 may be smaller than a horizontal area of the upper redistribution structure 260 and the lower redistribution structure 210. The footprint occupied by the first upper semiconductor chip 300 and the second upper semiconductor chip 400 may vertically overlap both the upper redistribution structure 260 and/or the lower redistribution structure 210. Some of the upper redistribution patterns of the upper redistribution structure 260 and some of the lower redistribution patterns of the lower redistribution structure 210 may extend to further protrude outward in a horizontal direction from the footprint occupied by the first upper semiconductor chip 300 and the second upper semiconductor chip 400 together.

The first upper semiconductor chip 300, the first passive element 220, and the first internal semiconductor chip 230 may overlap in the vertical direction. In an embodiment, as illustrated in FIG. 2, the first passive element 220 and the first internal semiconductor chip 230 may be arranged inside an outer edge of the first upper semiconductor chip 300 on a horizontal plane. If necessary, a plurality of first passive elements 220 may be included in the interposer 200.

The second upper semiconductor chip 400 and the first passive element 220 or the first internal semiconductor chip 230 may not overlap in the vertical direction. That is, the first passive element 220 or the first internal semiconductor chip 230 may not be arranged inside an outer edge of the second upper semiconductor chip 400 on a horizontal plane. Alternatively, in another embodiment, the first passive element 220 or the first internal semiconductor chip 230 may be arranged inside the outer edge of the second upper semiconductor chip 400 on the horizontal plane so that the second upper semiconductor chip 400 and the first passive element 220 or the first internal semiconductor chip 230 may overlap in the vertical direction.

As described above, the first upper semiconductor chip 300 may include a CPU chip, a GPU chip, or an AP chip. In addition, as described above, the second upper semiconductor chip 400 may include a DRAM chip, an SRAM chip, a flash memory chip, an EEPROM chip, a PRAM chip, an MRAM chip, or an RRAM chip. Due to characteristics of a chip, greater power may be supplied to the first upper semiconductor chip 300 than to the second upper semiconductor chip 400. Accordingly, in order to improve electrical characteristics of the semiconductor package 1, it may be necessary to arrange a capacitor closer to the first upper semiconductor chip 300.

Accordingly, the electrical characteristics of the first upper semiconductor chip 300 may be improved by arranging the first passive element 220 as a ceramic capacitor and the first internal semiconductor chip 230 as a silicon capacitor directly below the first upper semiconductor chip 300. For example, an impedance value for power in a specific band supplied to the first upper semiconductor chip 300 may be improved.

The first passive element 220 as a ceramic capacitor is connected to the lower redistribution structure 210 by the internal connection terminals 223 under the terminals 221 and is connected to the upper redistribution structure 260 on the terminals 221 through the intermediate connection vias 224. An electrical signal from the outside may not pass through the lower redistribution structure 210, the plurality of conductive posts 240, and the upper redistribution structure 260 to reach the capacitor, but may directly reach the first passive element 220 through the lower redistribution structure 210 due to a structure of the first passive element 220 being electrically connected to upper and lower portions. Accordingly, a transmission path of the electrical signal is reduced, and electrical characteristics including signal response characteristics of the semiconductor package 1 may be improved.

In addition, not only a silicon capacitor but also a ceramic capacitor is additionally provided so that the semiconductor package 1 may be equipped with not only the silicon capacitor but also the ceramic capacitor that is cheaper than the silicon capacitor. That is, required capacitance may be satisfied by the ceramic capacitor and the silicon capacitor. Therefore, economic feasibility of the semiconductor package 1 may be improved.

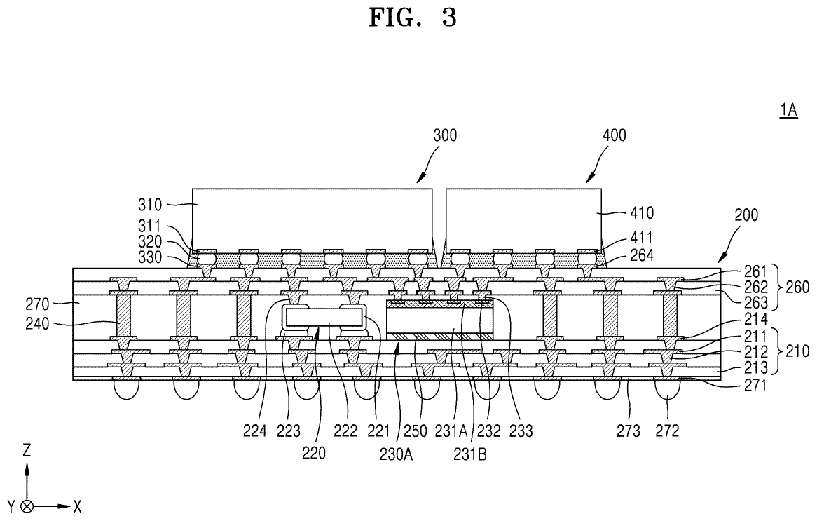

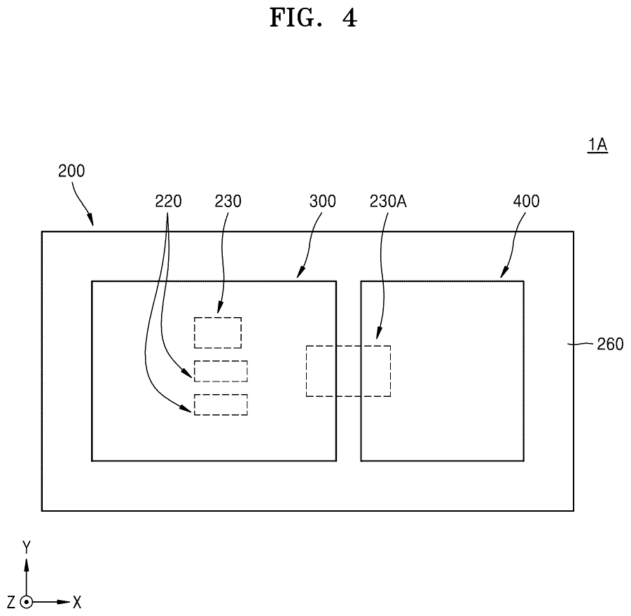

FIG. 3 is a cross-sectional view illustrating a semiconductor package 1A according to one of embodiments. FIG. 4 is a plan view illustrating a semiconductor package 1A according to one of embodiments. A difference from the semiconductor package 1 described in FIGS. 1 and 2 will be mainly described.

Referring to FIGS. 3 and 4, like in the semiconductor package 1 described in FIGS. 1 and 2, a first upper semiconductor chip 300 and a second upper semiconductor chip 400 may be arranged on an interposer 200. The first upper semiconductor chip 300 and the second upper semiconductor chip 400 may be laterally apart from each other.

The interposer 200 may include a first passive element 220, a first internal semiconductor chip 230, and a second internal semiconductor chip 230A. That is, the first passive element 220, the first internal semiconductor chip 230, and the second internal semiconductor chip 230A may be provided on a lower redistribution structure 210. The first passive element 220 and the first internal semiconductor chip 230 are substantially the same as those of the semiconductor package 1 described in FIGS. 1 and 2.

Like the first internal semiconductor chip 230, the second internal semiconductor chip 230A may be attached onto the lower redistribution structure 210 by a die adhesive film 250. In some embodiments, the second internal semiconductor chip 230A may be attached to a top surface of the uppermost layer among a plurality of lower insulating layers 213 included in the lower redistribution structure 210.

The second internal semiconductor chip 230A may include a second internal substrate 231A, a plurality of connection wiring patterns 231B, and internal chip pads 232. The second internal substrate 231A may be a semiconductor substrate. For example, the second internal substrate 231A may include Si.

The plurality of connection wiring patterns 231B may be formed on the second internal substrate 231A through a typical semiconductor device wiring process. The plurality of connection wiring patterns 231B may include connection line wiring forming one layer. However, inventive concepts are not limited thereto. In some embodiments, the plurality of connection wiring patterns 231B may include connection line wiring forming two or more layers and a via plug connecting the connection line wiring of different layers, and an inter-wire insulating layer may be formed between the connection line wiring and the via plug. The second internal semiconductor chip 230A may be formed by performing only a wiring process without forming an individual electronic device on the second internal substrate 231A. The second internal semiconductor chip 230A may be referred to as an internal interposer chip in the current specification.

The connection pillars 233 may connect the second internal semiconductor chip 230A to upper redistribution patterns of an upper redistribution structure 260. The connection pillars 233 may be arranged on the internal chip pads 232 to extend in the vertical direction and may be electrically connected to the upper redistribution patterns included in the upper redistribution structure 260.

Part of the second internal semiconductor chip 230A may overlap the first upper semiconductor chip 300 in the vertical direction. Part of the second internal semiconductor chip 230A, excluding part overlapping the first upper semiconductor chip 300 in the vertical direction, may overlap the second upper semiconductor chip 400 in the vertical direction. Part of the second internal semiconductor chip 230A does not overlap the first upper semiconductor chip 300 and the second upper semiconductor chip 400. As illustrated in FIG. 4, the second internal semiconductor chip 230A may be arranged so that part of the second internal semiconductor chip 230A overlaps the first upper semiconductor chip 300 and the second upper semiconductor chip 400 in the vertical direction. In the current specification, the first upper semiconductor chip 300 may be referred to as a main upper semiconductor chip, and the second upper semiconductor chip 400 may be referred to as a sub-upper semiconductor chip.

The first upper semiconductor chip 300 may be electrically connected to the outside through upper redistribution line patterns 261 and upper redistribution via patterns 262 of the upper redistribution structure 260, a plurality of conductive posts 240, and lower redistribution line patterns 211 and lower redistribution via patterns 212 of the lower redistribution structure 210. The second upper semiconductor chip 400 may be electrically connected to the outside through the plurality of upper redistribution line patterns 261 and the plurality of upper redistribution via patterns 262 of the upper redistribution structure 260, the plurality of conductive posts 240, and the plurality of lower redistribution line patterns 211 and the plurality of lower redistribution via patterns 212 of the lower redistribution structure 210.

The first upper semiconductor chip 300 and the second upper semiconductor chip 400 may be electrically connected to each other through the plurality of upper redistribution line patterns 261 and the plurality of upper redistribution via patterns 262 of the upper redistribution structure 260 and the second internal semiconductor chip 230A without passing through the plurality of lower redistribution line patterns 211 and the plurality of lower redistribution via patterns 212 of the lower redistribution structure 210 in the semiconductor package 1A.

For example, transmission of a power signal, a ground signal, a control signal, and a clock signal from the plurality of external connection terminals 272 to each of the first upper semiconductor chip 300 and the second upper semiconductor chip 400, and data transmission and/or reception between each of the first upper semiconductor chip 300 and the second upper semiconductor chip 400 and the plurality of external connection terminals 272 may be performed through the plurality of lower redistribution line patterns 211, the plurality of lower redistribution via patterns 212, and the plurality of conductive posts 240 of the lower redistribution structure 210 and the plurality of upper redistribution line patterns 261 and the plurality of upper redistribution via patterns 262 of the upper redistribution structure 260.

Meanwhile, for example, data transmission and/or reception between the first upper semiconductor chip 300 and the second upper semiconductor chip 400 and signal transmission for clock synchronization between the first upper semiconductor chip 300 and the second upper semiconductor chip 400 may be performed only through the plurality of upper redistribution line patterns 261 and the plurality of upper redistribution via patterns 262 of the upper redistribution structure 260 and the second internal semiconductor chip 230A without passing through the plurality of lower redistribution line patterns 211 and the plurality of lower redistribution via patterns 212 of the lower redistribution structure 210.

A signal between the first upper semiconductor chip 300 and the second upper semiconductor chip 400 are transmitted through the second internal semiconductor chip 230A capable of implementing a relatively fine pitch, and an electrical signal between each of the first upper semiconductor chip 300 and the second upper semiconductor chip 400 and the outside is transmitted through the plurality of conductive posts 240 and the lower redistribution structure 210 that may be produced at relatively low cost. In addition, part of the electrical signal between the first upper semiconductor chip 300 and the outside may be transmitted through the first passive element 220. The external electrical signal may be transmitted from an external device connected to the plurality of external connection terminals 272. Transmission of electrical signals may be understood in a reverse order as well.

In the semiconductor package 1A according to one of embodiments, through the second internal semiconductor chip 230A, manufacturing cost of the semiconductor package 1A may be reduced and yield of the semiconductor package 1A may be improved. As described above, due to the structure of the first passive element 220 being electrically connected to the upper and lower portions, the electrical signal from the outside may directly reach the first passive element 220 through the lower redistribution structure 210. Accordingly, the transmission path of the electrical signal may be reduced so that the electrical characteristics including the signal response characteristics of the semiconductor package 1A according to one of embodiments may be improved. Not only the silicon capacitor but also the ceramic capacitor is additionally provided so that the economic feasibility of the semiconductor package 1A according to one of embodiments may be improved. The electrical characteristics of the semiconductor package 1A according to one of embodiments may be improved by arranging the first passive element 220 as the ceramic capacitor and the first internal semiconductor chip 230 as the silicon capacitor directly below the first upper semiconductor chip 300.

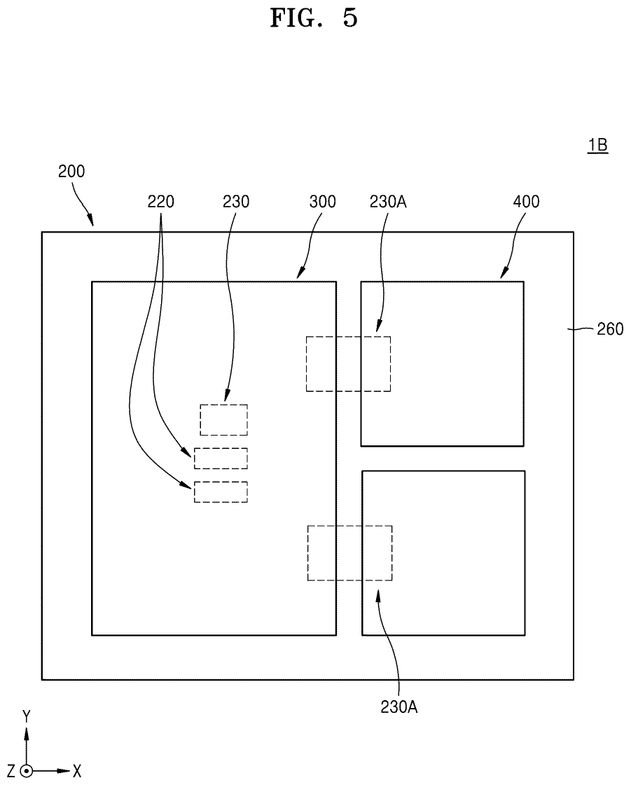

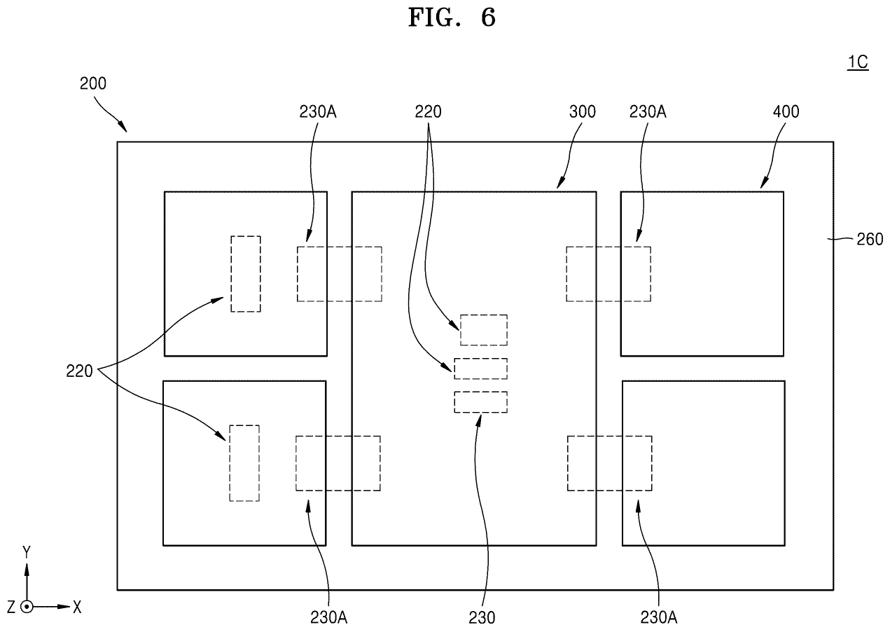

FIG. 5 is a plan view illustrating a semiconductor package 1B according to one of embodiments. FIG. 6 is a plan view illustrating a semiconductor package IC according to one of embodiments. Differences from the above-described semiconductor packages 1 and 1A will be mainly described.

Referring to FIG. 5, a first upper semiconductor chip 300 and two second upper semiconductor chips 400 may be arranged on an interposer 200. The first passive element 220 and the first internal semiconductor chip 230 may be arranged inside the outer edge of the first upper semiconductor chip 300 on the horizontal plane. The number of second internal semiconductor chips 230A equal to or greater than the number of second upper semiconductor chips 400 may be provided in the interposer 200. The second internal semiconductor chip 230A may not be provided between the two second upper semiconductor chips 400.

The first upper semiconductor chip 300 and each of the two second upper semiconductor chips 400 may be electrically connected to each other through the second internal semiconductor chip 230A. For example, data transmission and/or reception between the first upper semiconductor chip 300 and the two second upper semiconductor chips 400 and signal transmission for clock synchronization between the first upper semiconductor chip 300 and the two second upper semiconductor chips 400 may be performed only through the upper redistribution structure 260 and the second internal semiconductor chip 230A.

A plurality of first passive elements 220 may be provided in the interposer 200 as needed, and similarly, two or more first internal semiconductor chips 230 may be provided in the interposer 200 as needed. The first passive element 220 and the first internal semiconductor chip 230 may not be arranged inside the outer edge of the second upper semiconductor chip 400 on the horizontal plane. However, inventive concepts are not limited thereto.

Referring to FIG. 6, a first upper semiconductor chip 300 and four second upper semiconductor chips 400 may be arranged on an interposer 200. The first passive element 220 and the first internal semiconductor chip 230 may be arranged inside the outer edge of the first upper semiconductor chip 300 on the horizontal plane. The number of second internal semiconductor chips 230A equal to the number of second upper semiconductor chips 400 may be provided in the interposer 200. A second internal semiconductor chip 230A may not be provided between a second upper semiconductor chip 400 and another second upper semiconductor chip 400.

The first upper semiconductor chip 300 and each of the four second upper semiconductor chips 400 may be electrically connected to each other through the second internal semiconductor chip 230A. For example, data transmission and/or reception between the first upper semiconductor chip 300 and the four second upper semiconductor chips 400 and signal transmission for clock synchronization between the first upper semiconductor chip 300 and the four second upper semiconductor chips 400 may be performed only through the upper redistribution structure 260 and the second internal semiconductor chip 230A.

Two or more first passive elements 220 may be provided in the interposer 200 as needed, and similarly, two or more first internal semiconductor chips 230 may be provided in the interposer 200 as needed. The first passive element 220 or the first internal semiconductor chip 230 may not be arranged inside the outer edge of the second upper semiconductor chip 400 on the horizontal plane. Alternatively, the first passive element 220 and the first internal semiconductor chip 230 may be arranged inside the outer edge of the second upper semiconductor chip 400 on the horizontal plane.

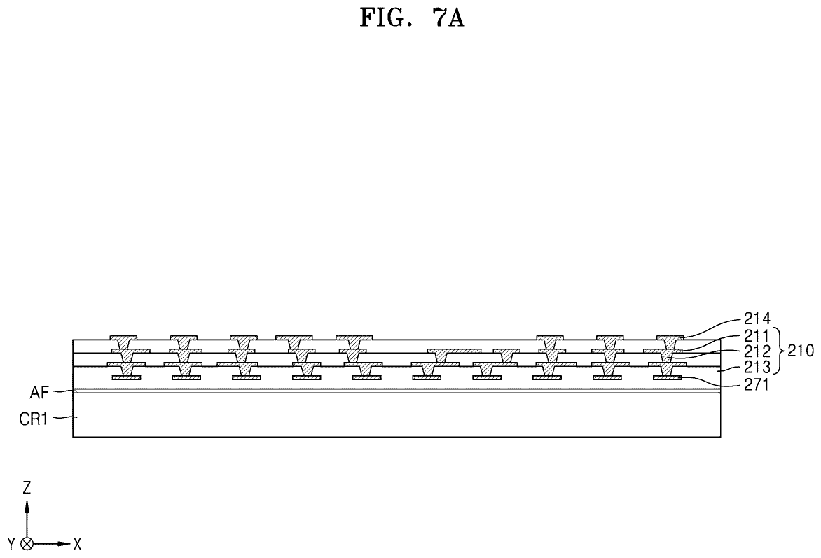

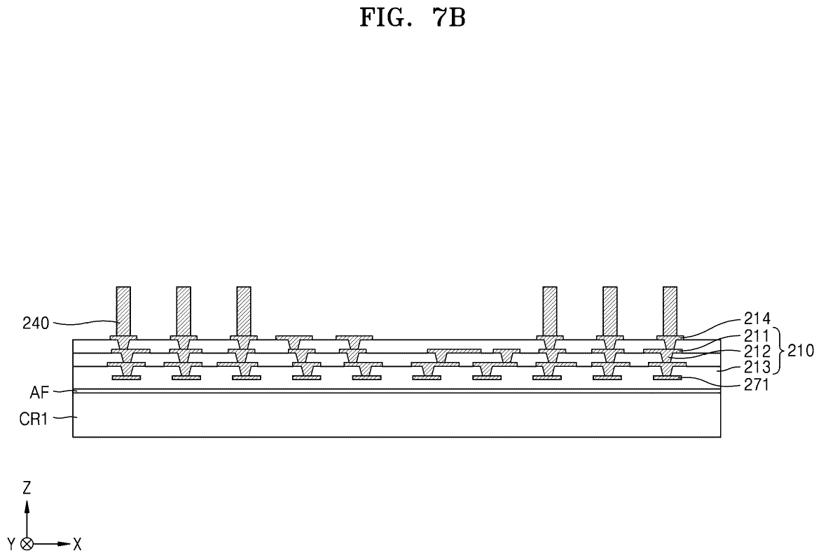

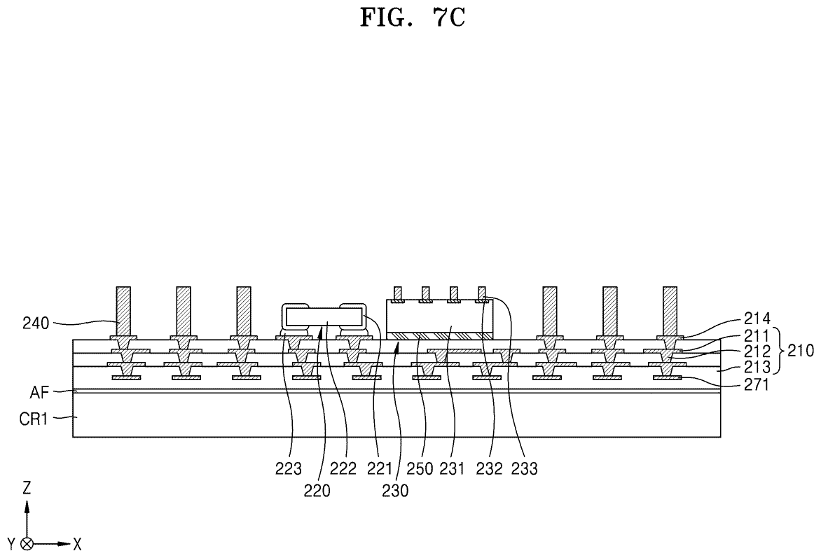

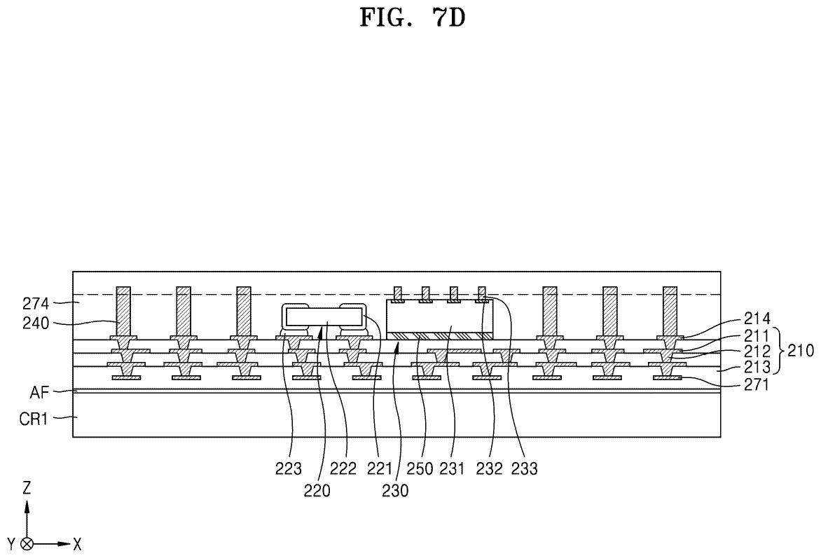

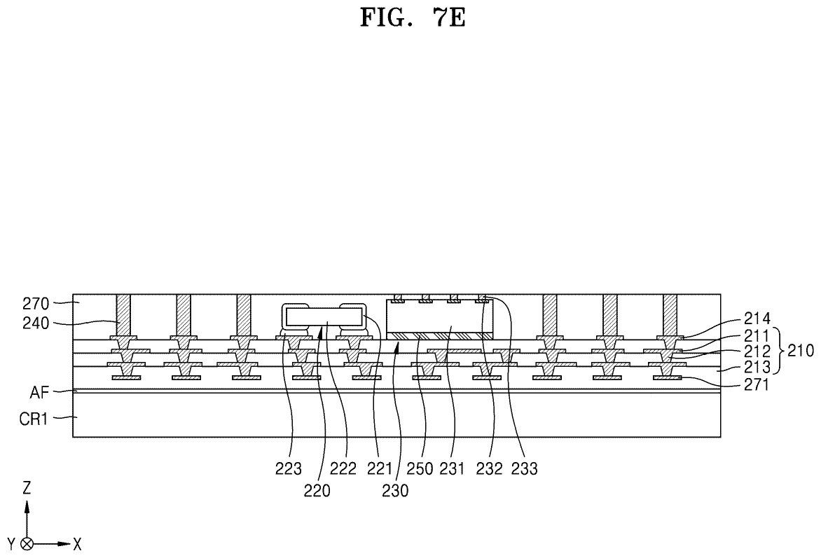

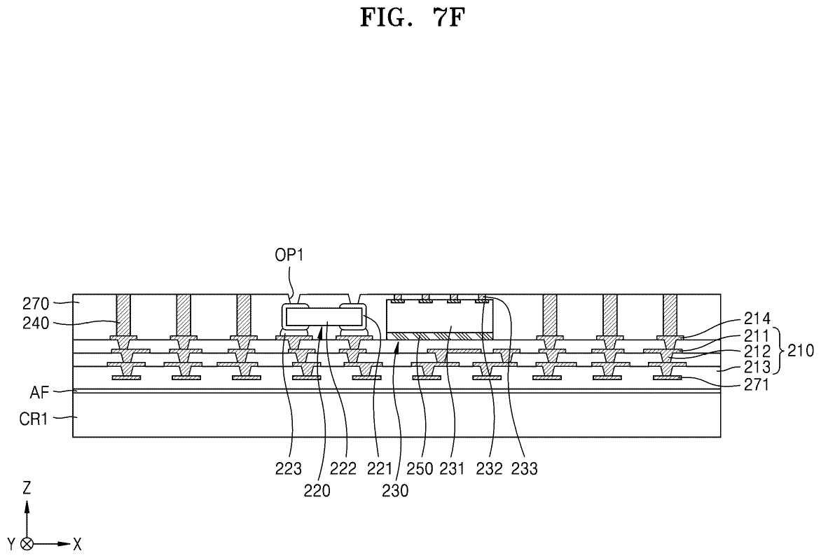

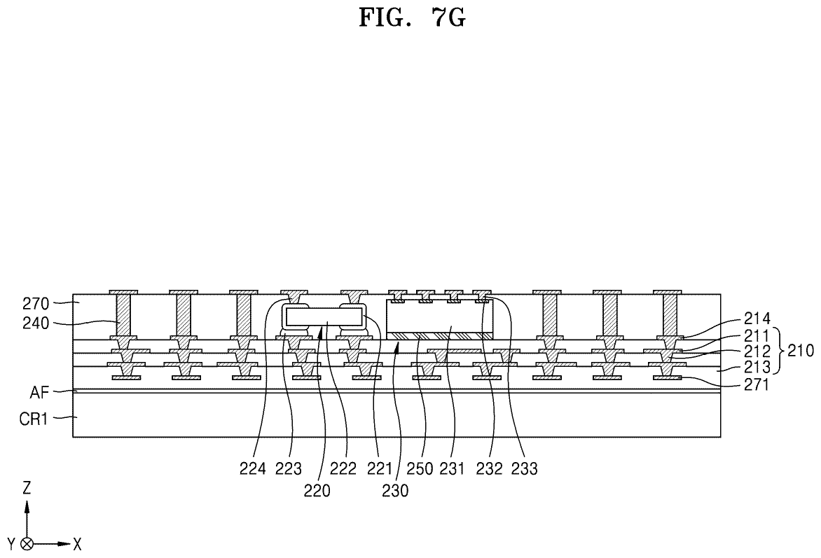

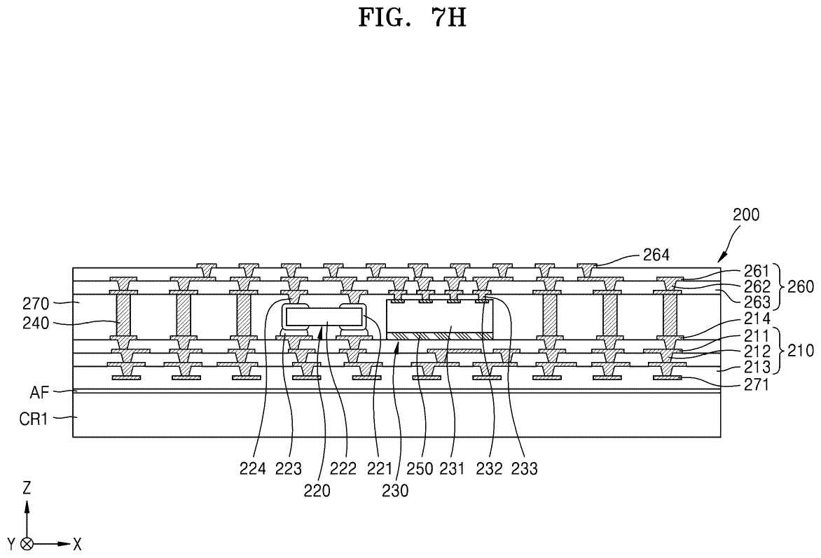

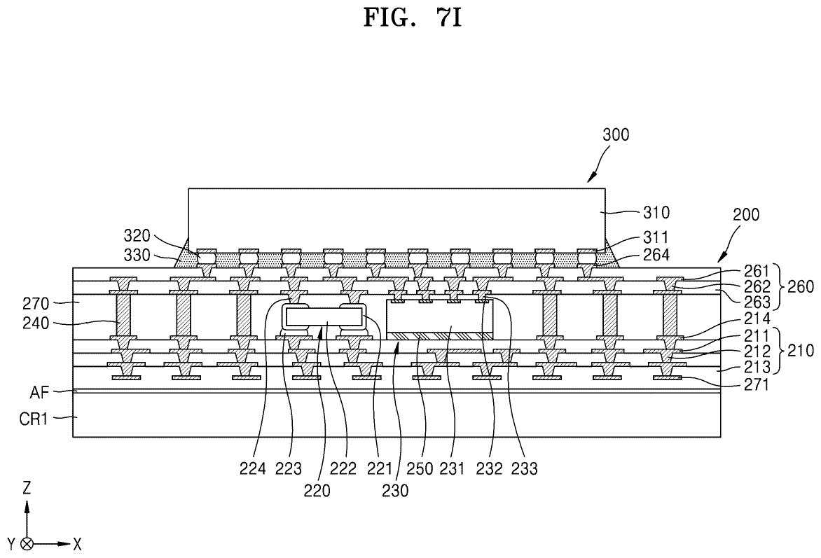

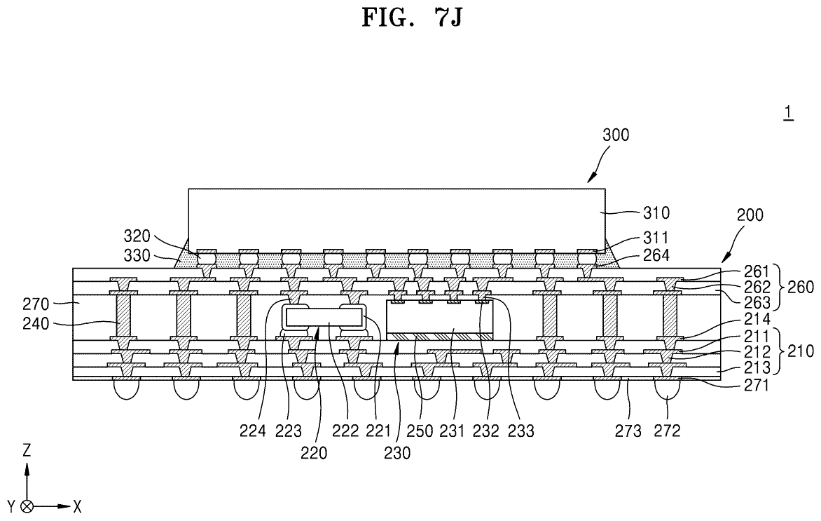

FIGS. 7A to 7J are cross-sectional views illustrating a method of manufacturing a semiconductor package according to one of embodiments. Specifically, FIGS. 7A to 7J are cross-sectional views illustrating the method of manufacturing the semiconductor package 1 of FIG. 1 step by step.

Referring to FIG. 7A, the lower redistribution structure 210 is formed on a carrier substrate CRI to which a release film AF is attached. The lower redistribution structure 210 may include the plurality of lower insulating layers 213, the plurality of lower redistribution line patterns 211 respectively arranged on top or bottom surfaces of the plurality of lower insulating layers 213, and the plurality of lower redistribution via patterns 212 respectively passing through the plurality of lower insulating layers 213.

The lower redistribution structure 210 may be formed by sequentially stacking each of the plurality of lower insulating layers 213, the plurality of lower redistribution line patterns 211 or the plurality of lower redistribution via patterns 212, and the plurality of lower redistribution line patterns.

Referring to FIG. 7B, the plurality of conductive posts 240 are formed on the lower redistribution structure 210, on the uppermost surface of the lower redistribution structure 210, and on the plurality of internal connection pads 214.

After forming a mask pattern opening a position in which the plurality of conductive posts 240 are formed on the lower redistribution structure 210, electroless plating is performed on the plurality of exposed internal connection pads 214 to form the plurality of conductive posts 240. In some embodiments, after forming a seed layer on the lower redistribution structure 210 and performing electroless plating on the seed layer to form a conductive material layer, the mask pattern is removed to form the plurality of conductive posts 240.

Referring to FIG. 7C, the first internal semiconductor chip 230 and the first passive element 220 are attached onto the lower redistribution structure 210. The first passive element 220 and the first internal semiconductor chip 230 may be arranged on the lower redistribution structure 210 to be laterally apart from the plurality of conductive posts 240. The first internal semiconductor chip 230 may be attached onto the lower redistribution structure 210 by, for example, the die adhesive film 250. The first internal semiconductor chip 230 may be attached to the top surface of the uppermost layer among the plurality of lower insulating layers 213 included in the lower redistribution structure 210. The first passive element 220 may be arranged on the lower redistribution structure 210 through a surface mounting facility so that the first passive element 220 may be attached to part of the plurality of internal connection pads 214 through the internal connection terminals 223.

Like the first internal semiconductor chip 230 described above, the second internal semiconductor chip 230A of the semiconductor package 1A illustrated in FIGS. 3 and 4 may be attached onto the lower redistribution structure 210 by the die adhesive film 250.

Referring to FIG. 7D, an encapsulant 274 covering the connection pillars 233, the plurality of conductive posts 240, the first passive element 220, and the first internal semiconductor chip 230 is formed on the lower redistribution structure 210. The encapsulant 274 may include an epoxy molding compound (EMC) or a polymer material.

Referring to FIG. 7E, the encapsulant 270 is formed by partially removing an upper side of the encapsulant 274 illustrated in FIG. 7D so that the plurality of conductive posts 240 and the connection pillars 233 are exposed. In the process of partially removing the upper side of the encapsulant 274, the plurality of conductive posts 240 and the connection pillars 233 may be partially removed together. The encapsulant 270 may cover the top surface of the lower redistribution structure 210, side surfaces of the plurality of conductive posts 240, and side surfaces of the connection pillars 233. That is, the encapsulant 270 may cover the side surfaces of the plurality of conductive posts 240 and the connection pillars 233, but may expose top surfaces of the plurality of conductive posts 240 and the connection pillars 233 without covering the top surfaces of the plurality of conductive posts 240 and the connection pillars 233. Accordingly, the top surfaces of the plurality of conductive posts 240, the top surfaces of the connection pillars 233, and the top surface of the encapsulant 270 may be coplanar.

Referring to FIG. 7F, openings OP1 may be formed in the top surface of the encapsulant 270 so that at least parts of the terminals 221 of the first passive element 220 are exposed to the outside. For example, the openings OP1 may be formed in the top surface of the encapsulant 270 through laser processing so that at least parts of the terminals 221 of the first passive element 220 are exposed to the outside. For example, the opening OP1 may have a tapered shape of which horizontal width increases away from the lower redistribution structure 210.

Referring to FIG. 7G, redistribution patterns respectively connected to the plurality of intermediate connection vias 224 may be formed in the openings OP1 of FIG. 7F and redistribution patterns respectively connected to the plurality of conductive posts 240, the plurality of intermediate connection vias 224, and the plurality of connection pillars 233 may be formed on the top surface of the encapsulant 270 of FIG. 7F. The intermediate connection vias 224 and the redistribution patterns may be formed by performing electroless plating. In some embodiments, after forming a seed layer in part of the openings OP1 and the top surface of the encapsulant 270, electroless plating is performed on the seed layer to form the plurality of intermediate connection vias 224 and the redistribution patterns. However, inventive concepts are not limited to the above-described method of forming the intermediate connection vias 224 and the redistribution patterns. The top surfaces of the plurality of conductive posts 240, the top surfaces of the connection pillars 233, the top surface of the encapsulant 270, and top surfaces of the intermediate connection vias 224 may be coplanar.

Referring to FIG. 7H, the upper redistribution structure 260 including the redistribution patterns formed on the top surface of the encapsulant 270 of FIG. 7F is formed. The upper redistribution structure 260 may include the at least one upper insulating layer 263, the plurality of upper redistribution line patterns 261 arranged on the top or bottom surface of the at least one upper insulating layer 263, and the plurality of upper redistribution via patterns 262 penetrating the upper insulating layer 263.

The upper redistribution structure 260 may be formed by sequentially stacking the plurality of upper redistribution line patterns 261 or the plurality of upper redistribution via patterns 262 and the plurality of upper redistribution line patterns 261, and the upper insulating layer 263.

Referring to FIG. 7I, the first upper semiconductor chip 300 is attached onto the upper redistribution structure 260. The plurality of first chip pads 311 of the first upper semiconductor chip 300 may be connected to the plurality of upper connection pads 264 of the upper redistribution structure 260 through the plurality of chip connection members 320, respectively. The underfill material layer 330 surrounding the plurality of chip connection members 320 may fill the space between the first upper semiconductor chip 300 and the upper redistribution structure 260. The second upper semiconductor chip 400 of the semiconductor package 1A illustrated in FIGS. 3 and 4 may also be attached onto the upper redistribution structure 260 like the first upper semiconductor chip 300.

Referring to FIG. 7J, the carrier substrate Cl to which the release film AF illustrated in FIG. 7I is attached is separated from the lower redistribution structure 210. Thereafter, part of the lowermost lower insulating layer 213 among the plurality of lower insulating layers 213 may be removed to expose the plurality of external connection pads 271. After forming a passivation layer 273, the plurality of external connection terminals 272 may be formed on the plurality of external connection pads 271, respectively.

While inventive concepts has been particularly shown and described with reference to embodiments thereof, it will be understood that various changes in form and details may be made therein without departing from the spirit and scope of the following claims.

What is claimed is:

1. A semiconductor package comprising:
a first upper semiconductor chip; and
a first interposer, the first upper semiconductor chip being on a top surface of the first interposer, wherein
the first interposer includes a lower redistribution structure, an upper redistribution structure, conductive posts between the lower redistribution structure and the upper redistribution structure, a first passive element, and a first internal semiconductor chip,
the lower redistribution structure includes a lower redistribution pattern and a lower insulating layer,
the upper redistribution structure includes an upper redistribution pattern and an upper insulating layer above the lower redistribution structure, wherein
the first passive element and the first internal semiconductor chip are between the upper redistribution structure and the lower redistribution structure and laterally apart from the conductive posts, and
the first passive element is a ceramic capacitor.

2. The semiconductor package of claim 1, wherein
the first passive element is connected to the upper redistribution pattern through an intermediate connection via, and
the intermediate connection via extends from a top surface of the first passive element to the upper redistribution structure.

3. The semiconductor package of claim 2, further comprising:
internal connection terminals, wherein
the first passive element and the lower redistribution pattern are connected through internal connection terminals.

4. The semiconductor package of claim 3, wherein
the intermediate connection via is connected to upper portions of both ends of the first passive element, respectively, and
the internal connection terminals are connected to lower portions of both ends of the first passive element, respectively.

5. The semiconductor package of claim 3, wherein the first passive element vertically overlaps the first upper semiconductor chip.

6. The semiconductor package of claim 4, wherein
the intermediate connection via, the first passive element, and the internal connection terminals are configured to pass a part of a signal transmitted between the first upper semiconductor chip and the lower redistribution structure.

7. The semiconductor package of claim 1, wherein
the first internal semiconductor chip comprises a silicon capacitor, and
the first internal semiconductor chip vertically overlaps the first upper semiconductor chip.

8. The semiconductor package of claim 7, further comprising:
an adhesive film between the first internal semiconductor chip and the lower redistribution structure, wherein
the first internal semiconductor chip is connected to the upper redistribution pattern by a connection pillar.

9. The semiconductor package of claim 8, further comprising:
an intermediate encapsulant between the upper redistribution structure and the lower redistribution structure, wherein
the intermediate encapsulant surrounds the first passive element, the first internal semiconductor chip, the connection pillar, and the conductive posts.

10. The semiconductor package of claim 1, wherein
the first interposer further includes a second upper semiconductor chip and a second internal semiconductor chip,
the second upper semiconductor chip is laterally apart from the first upper semiconductor chip and on the top surface of the first interposer,
the second internal semiconductor chip is between the upper redistribution structure and the lower redistribution structure and laterally apart from the conductive posts,
a first part of the second internal semiconductor chip vertically overlaps the first upper semiconductor chip,
a second part of the second internal semiconductor chip vertically overlaps the second upper semiconductor chip, and
a rest of the second internal semiconductor chip does not vertically overlap the first upper semiconductor chip and the second upper semiconductor chip.

11. The semiconductor package of claim 10, wherein
the upper redistribution structure and the second internal semiconductor chip are configured to perform signal transmission between the first upper semiconductor chip and the second upper semiconductor chip.

12. The semiconductor package of claim 1, wherein
the upper redistribution structure comprises a plurality of upper insulating layers,
the lower redistribution structure comprises a plurality of lower insulating layers, and
a number of layers of the plurality of lower insulating layers is equal to or greater than a number of layers of the plurality of upper insulating layers.

13. A semiconductor package comprising:
a lower redistribution structure including a lower redistribution pattern and a plurality of lower insulating layers;
conductive posts, a passive element, and internal semiconductor chips, laterally apart from each other on the lower redistribution structure;
an upper redistribution structure connected to the conductive posts, the passive element and the internal semiconductor chips, respectively, the upper redistribution structure being on the conductive posts, the passive element, and the internal semiconductor chips, and the upper redistribution structure including an upper redistribution pattern and a plurality of upper insulating layers;
an encapsulant covering the conductive posts, the passive element, and the internal semiconductor chips, the encapsulant between the upper redistribution structure and the lower redistribution structure;
intermediate connection vias connected to upper portions of both terminals of the passive element, respectively;
internal connection terminals are connected to lower portions of both terminals of the passive element, respectively;
a connection pillar connecting the internal semiconductor chips to the upper redistribution pattern; and
upper semiconductor chips laterally apart from each other on the upper redistribution structure, wherein
the passive element is a ceramic capacitor,
the intermediate connection vias extend through the encapsulant from top surfaces of both terminals of the passive element to the upper redistribution structure,
the intermediate connection vias are connected to the upper redistribution pattern, and
the internal connection terminals are connected to the lower redistribution pattern.

14. The semiconductor package of claim 13, wherein
the upper semiconductor chips comprise a main upper semiconductor chip and sub-upper semiconductor chips,
the internal semiconductor chips comprise a first internal semiconductor chip and second internal semiconductor chips,
the first internal semiconductor chip vertically overlaps the main upper semiconductor chip,
parts of the second internal semiconductor chips vertically overlap the main upper semiconductor chip,
other parts of the second internal semiconductor chips vertically overlap the sub-upper semiconductor chips, respectively, and
the upper redistribution structure and the second internal semiconductor chips are configured to perform signal transmission between the main upper semiconductor chip an the sub-upper semiconductor chips.

15. The semiconductor package of claim 14, wherein a number of the second internal semiconductor chips is equal to or greater than a number of the sub-upper semiconductor chips.

16. The semiconductor package of claim 14, wherein
the passive element comprises a first passive element and a plurality of second passive elements, and
the first passive element vertically overlaps the main upper semiconductor chip, and
at least one of the plurality of second passive elements vertically overlaps the sub-upper semiconductor chips.

17. The semiconductor package of claim 13, wherein top surfaces of the conductive posts, a top surface of the intermediate connection vias, a top surface of the connection pillar, and a top surface of the encapsulant are coplanar.

18. The semiconductor package of claim 13, wherein
the intermediate connection via has a tapered shape of which a horizontal width increases away from the lower redistribution structure.

19. The semiconductor package of claim 13, wherein
the upper redistribution pattern comprises an upper redistribution line pattern and an upper redistribution via pattern,
the lower redistribution pattern comprises a lower redistribution line pattern and a lower redistribution via pattern, and
each of the upper redistribution via pattern and the lower redistribution via pattern has a tapered shape of which a width decreases in a vertical direction away from the upper semiconductor chips.

20. A semiconductor package comprising:
a first upper semiconductor chip;
a second upper semiconductor chip laterally apart from the first upper semiconductor chip;
a first interposer, the first upper semiconductor chip and the second upper semiconductor chip being on a top surface of the first interposer,
the first interposer including a lower redistribution structure, an upper redistribution structure, conductive posts between the lower redistribution structure and the upper redistribution structure, a first passive element, a first internal semiconductor chip, a second internal semiconductor chip, and an encapsulant,
the lower redistribution structure including a lower redistribution pattern and a lower insulating layer,
the upper redistribution structure including an upper redistribution pattern and an upper insulating layer,
the first passive element, the first internal semiconductor chip, and the second internal semiconductor chip being between the upper redistribution structure and the lower redistribution structure and laterally apart from the conductive posts,
the encapsulant covering the conductive posts, the first passive element, the first internal semiconductor chip, and the second internal semiconductor chip and the encapsulant between the upper redistribution structure and the lower redistribution structure;
intermediate connection vias connected to upper portions of both terminals of the first passive element;
internal connection terminals are connected to lower portions of both terminals of the passive element, respectively;
a connection pillar connecting the upper redistribution pattern to the first internal semiconductor chip and the second internal semiconductor chip; and
an adhesive film between the first internal semiconductor chip and the lower redistribution structure; wherein
the first passive element is a ceramic capacitor and vertically overlaps the first upper semiconductor chip,
the intermediate connection vias extend through the encapsulant from top surfaces of both terminals of the passive element to the upper redistribution structure and are connected to the upper redistribution pattern,
the internal connection terminals are connected to the lower redistribution pattern,
the intermediate connection via, the first passive element, and the internal connection terminals are configured to pass part of a signal transmitted between the first upper semiconductor chip and the lower redistribution structure,
the first internal semiconductor chip comprises a silicon capacitor,
the first internal semiconductor chip vertically overlaps the first upper semiconductor chip,
a part of the second internal semiconductor chip vertically overlaps the first upper semiconductor chip,
an other part of the second internal semiconductor chip vertically overlaps the second upper semiconductor chip,
a rest of the second internal semiconductor chip does not vertically overlap the first upper semiconductor chip and the second upper semiconductor chip,
the upper redistribution structure and the second internal semiconductor chip are configured to perform signal transmission between the first upper semiconductor chip and the second upper semiconductor chip, and
top surfaces of the conductive posts, a top surface of the intermediate connection via, a top surface of the connection pillar, and a top surface of the encapsulant are coplanar.
